(19) United States
(12) Patent Application Publication
(10) Pub. No.: US 2006/0244074 A1
(43) Pub. Date: Nov. 2, 2006

(54) Hybrid-strained sidewall spacer for CMOS process

(76) Inventors: Chien-Hao Chen, Chuangwei Township (TW); Kai-Ting Tseng, Taichung (TW); Tze-Liang Lee, Hsinchu (TW)

Correspondence Address: SLATER & MATSIL, L.L.P., 17950 PRESTON ROAD, SUITE 1000, DALLAS, TX, 75252, US

(21) Appl. No.: 11/119,272

(22) Filed: Apr. 29, 2005

(51) Int. Cl. H01L 29/76

(52) U.S. Cl. 257/371

(57) ABSTRACT

Embodiments of the invention provide a semiconductor device and a method of manufacture. MOS devices along with their gate electrode sidewall spacers are fabricated such that the orientation of the intrinsic stress in the sidewall spacers is opposite to the stress created in the channel. An embodiment includes selectively patterning a compressive stress layer to form NMOS electrode sidewall spacers, wherein the compressive NMOS electrode sidewall spacers create a tensile stress in a NMOS channel. Another embodiment comprises selectively patterning a tensile stress layer to form tensile PMOS electrode sidewall spacers, wherein the PMOS electrode sidewall spacers create a compressive stress in a PMOS channel. Still other embodiments of the invention provide a semiconductor device having strained sidewall spacers. In one embodiment, a spacer having an intrinsic stress comprising one of tensile and compressive corresponds to a channel stress that is the other of tensile and compressive.

### TECHNICAL FIELD

This invention relates generally to semiconductors devices, and more specifically to methods and structures for introducing stress into CMOS devices in order to improve charge carrier mobility.

### BACKGROUND

Size reduction of metal-oxide-semiconductor field-effect transistors (MOSFETs) has enabled the continued improvement in speed performance, density, and cost per unit function of integrated circuits. One way to improve transistor performance is through selective application of stress to the transistor channel region. Stress distorts (i.e., strains) the semiconductor crystal lattice, and the distortion, in turn, affects the band alignment and charge transport properties of the semiconductor. By controlling the magnitude and distribution of stress in a finished device, manufacturers can increase carrier mobility and improve device performance. There are several existing approaches of introducing stress in the transistor channel region.

One conventional approach includes forming an epitaxial, strained silicon layer on a relaxed silicon germanium (SiGe) layer. Since SiGe has a larger lattice constant than Si, the epitaxial Si grown on SiGe will have its lattice stretched in the lateral direction, i.e., the Si will be under biaxial tensile stress. In this approach, the relaxed SiGe buffer layer is referred to as a stressor that introduces stress in the channel region. The stressor, in this case, is placed below the transistor channel region.

In another approach, stress in the channel is introduced after the transistor is formed. In this approach, a high-stress film is formed over a completed transistor. The high-stress film distorts the silicon lattice thereby straining the channel region. In this case, the stressor, i.e., the film, is placed above the completed transistor structure.

One problem facing CMOS manufacturing is that NMOS and PMOS devices require different types of stress in order to achieve increased carrier mobility. For example, a biaxial, tensile stress increases NMOS performance approximately twofold. However, for a PMOS device, such a stress yields almost no improvement. With a PMOS device, a tensile stress improves performance when its perpendicular to the channel, but it has nearly the opposite effect when it is parallel to the channel. Therefore, when a biaxial, tensile film is applied to a PMOS device, the two stress effects almost cancel each other out.

Workers are aware of these problems. Therefore, new CMOS manufacturing techniques selectively address PMOS and NMOS devices. An NMOS fabrication method includes using tensile films to improve carrier mobility. A PMOS fabrication method includes using substrate structures that apply a compression stress to the channel. One PMOS method includes selective application of a SiGe layer into the source/drain regions. Another method uses modified shallow trench isolation (STI) structures that compress the PMOS channel.

The use of additional materials, however, adds further processing steps and complexity to the manufacturing process. Therefore, there remains a need for improving the carrier mobility of both NMOS and PMOS devices without significantly adding to the cost or complexity of the manufacturing process.

### SUMMARY OF THE INVENTION

These and other problems are generally solved or circumvented, and technical advantages are generally achieved by preferred embodiments of the present invention that provide methods and structures for introducing stress into MOS and CMOS devices in order to improve charge carrier mobility.

A preferred embodiment of the invention provides a method of semiconductor device fabrication. Embodiments comprise forming an NMOS and a PMOS device in a substrate and forming a stress layer, preferably a compressive stress layer, over the NMOS and PMOS devices. An embodiment further comprises adjusting a stress property of the stress layer over one type of device, preferably the PMOS device. In embodiments of the invention, adjusting a stress property comprises changing the compressive stress to a tensile stress in the stress layer. Embodiments further include patterning the compressive stress layer to form NMOS electrode sidewall spacers. Preferably, the NMOS electrode sidewall spacers create a tensile stress in an NMOS channel. Embodiments further include patterning the tensile stress layer to form PMOS electrode sidewall spacers. Preferably, the PMOS electrode sidewall spacers create a compressive stress in a PMOS channel.

The substrate may comprise silicon, silicon germanium, or combinations thereof. The compressive stress layer may comprise a silicon-rich nitride, a nitrided silicon oxide, a silicon nitride, and combinations thereof. Preferably, the compressive stress layer includes a region characterized by between about 500 MPa and 3 GPa compressive stress, and the tensile stress layer includes a region characterized by between about 500 MPa and 3 GPa tensile stress.

An alternate embodiment comprises forming an NMOS device and a PMOS device in a substrate, wherein each device has a channel connecting a source/drain region, and a gate electrode over the channel. An embodiment comprises forming a stress layer, preferably a compressive layer, over the NMOS device and the PMOS device, wherein the compressive layer creates a tensile channel stress substantially aligned with the channel. An embodiment comprises treating the compressive layer over the PMOS device so that the tensile channel stress changes from a first stress to a second stress. Embodiments further comprise etching the stress layer to form electrode sidewall spacers in the NMOS device and the PMOS device, wherein the electrode sidewall spacers in the NMOS device apply a tensile stress substantially parallel to a NMOS channel. Preferably, the electrode sidewall spacers in the NMOS device apply a tensile stress to the a NMOS channel

Still other embodiments of the invention provide a semiconductor device. The device comprises an NMOS transistor having an NMOS gate electrode spacer, wherein the NMOS gate electrode spacer comprises a material having an intrinsic compressive stress. The device comprises a PMOS transistor having a PMOS gate electrode spacer, wherein the PMOS gate electrode spacer comprises a material having an intrinsic second stress. Preferably, the NMOS gate electrode spacer creates a tensile stress in an NMOS carrier channel, and the PMOS gate electrode spacer creates a third stress in a PMOS carrier channel.

In an embodiment, the second stress comprises a compressive stress. In another embodiment, the second stress comprises a tensile stress. Preferably, the spacer is a D-shaped spacer or the spacer includes a D-shaped part. Preferably, the NMOS carrier channel and the PMOS carrier channel are less than about 100 nm.

In an embodiment, the NMOS gate electrode spacer comprises a material having a first intrinsic stress, which creates a third stress in an NMOS carrier channel. In another embodiment, the PMOS gate electrode spacer comprises a material having a second intrinsic stress, which creates a fourth stress in a PMOS carrier channel. Preferably, the first intrinsic stress is one of compressive and tensile, and the third stress is the other of compressive and tensile. In addition, the second intrinsic stress is preferably one of compressive and tensile, and the fourth stress is the other of compressive and tensile.

Note that although the term layer is used throughout the specification and in the claims, the resulting features formed using the layer should not be interpreted as only a continuous or uninterrupted feature. As will be clear from reading the specification, the semiconductor layer may be separated into distinct and isolated features (e.g., active regions), some or all of which comprise portions of the semiconductor layer.

Additional features and advantages of embodiments of the invention will be described hereinafter, which form the subject of the claims of the invention. It should be appreciated by those skilled in the art that the specific embodiments disclosed might be readily utilized as a basis for modifying or designing other structures or processes for carrying out the purposes of the present invention. It should also be realized by those skilled in the art that such equivalent constructions and variations on the example embodiments described do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of an intermediate stage in the manufacture of a CMOS device according to embodiments of the invention;

FIG. 2 is a cross-sectional view illustrating a stress layer over an intermediate CMOS device according to embodiments of the invention;

FIG. 3 is a cross-sectional view illustrating a selective treatment of a portion of the stress layer according to embodiments of the invention;

FIG. 4 is a cross-sectional view illustrating a stress layer having a first intrinsic stress region and a second intrinsic stress region according to embodiments of the invention; and

FIG. 5 is a cross-sectional view illustrating electrode spacers for inducing stress in a MOSFET channel according an embodiment of the invention.

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention. The intermediated stages of manufacturing a preferred embodiment of the present invention are illustrated throughout the various views and illustrative embodiments of the present invention. To more clearly illustrate certain embodiments, a letter indicating variations of the same structure, material, or process step may follow a figure number.

This invention relates generally to semiconductor device fabrication and more particularly to structures and methods for strained transistors. The present invention will now be described with respect to preferred embodiments in a specific context, namely the creation of a CMOS device. It is believed that embodiments of this invention are particularly advantageous when used in this process. It is believed that embodiments described herein will benefit other applications not specifically mentioned. Therefore, the specific embodiments discussed are merely illustrative of specific ways to make and use the invention, and do not limit the scope of the invention.

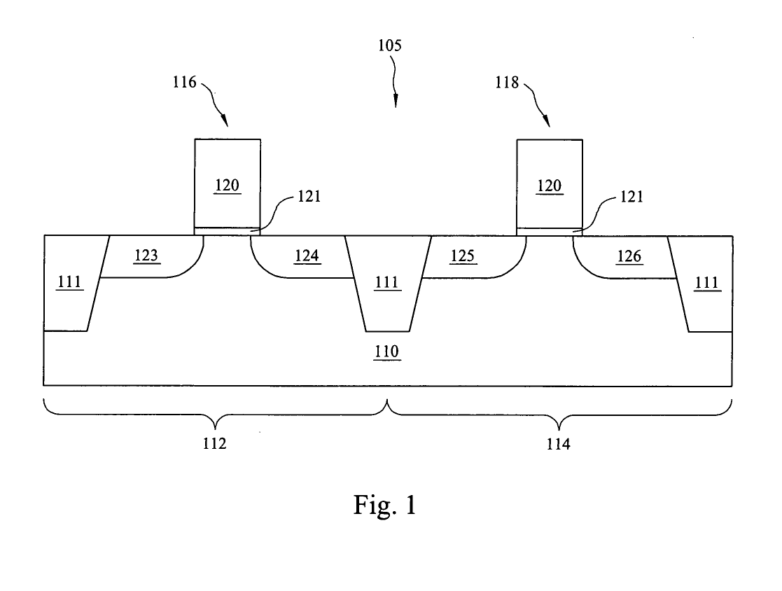

FIG. 1 illustrates a CMOS device 105 in an embodiment of the invention. CMOS device 105 includes a substrate 110 that preferably includes at least one NMOS region 112 having at least one NMOS (N-type MOS) device 116 formed therein and at least one PMOS region 114 having at least one PMOS (P-type MOS) device 118 formed therein. The substrate 110 may comprise Si, Ge, SiGe, GaAs, GaAlAs, InP, GaN, and combinations thereof. The substrate 110 may further include hybrid orientation substrates fabricated with silicon on insulator (SOI) technology. An isolation device 111, such as a shallow trench isolation (STI) structure, may be formed within the substrate 110 between the NMOS 116 and PMOS devices 118. The operation voltage for MOS transistor devices is preferably from about 0.6 to 3.3 volts (V) and is more preferably less than about 1.2 V. While the embodiment in FIG. 1 illustrates adjacent NMOS/PMOS devices, alternative embodiments may include devices that are not adjacent. One skilled in the art will recognize that multiple NMOS and PMOS regions will be arranged in various patterns on a typical integrated circuit and is within the contemplation of the present invention.

In alternative embodiments (not illustrated), STI structures may be optimized to selectively induce stress in n-channel and p-channel transistors separately. For example, a first isolation trench includes a first liner, and a second isolation trench includes a second liner, or none at all. By way of example, a liner may be a nitride layer. The second trench may be lined with a nitride layer that has been modified, e.g., implanted with ions or removed. In another example, the first material can be an oxynitride (a nitrided oxide). In this case, the second trench may be lined with an oxide liner or no liner at all, as examples. A liner can then be modified in some but not all of the plurality of trenches.

Continuing with FIG. 1, NMOS device 116 includes a source 123 and a drain 124 region, and PMOS device 118 includes its source 125 and drain 126 regions. The source/drain regions are implanted using methods known in the art. Each MOS device further includes a gate electrode 120 and a gate dielectric 121. Underlying the gate electrode 120 and the gate dielectric 121 is a charge carrier channel region connecting each device's respective source and drain regions. Because a conventional source/drain implant uses the gate electrode 120 and gate electrode spacers as an implant mask, the source/drain implant may be performed after forming the electrode spacers as described below according to embodiments of the invention.

In alternative embodiments, the channel/substrate orientation may be selected with a view towards optimizing the appropriate charge carrier mobility using SOI hybrid orientation substrates. For example, an NMOS channel may be oriented along the <100> the direction, which is the direction of maximum electron mobility for a {100} substrate. Alternatively, a PMOS channel may be oriented along the <110> direction, which is the direction where hole mobility is maximum for a {110} substrate. The respective device channel has a design width from about 0.05 to 10.0 μm, and preferably less than about 0.5 μm.

Gate dielectric 121 may include silicon oxide having a thickness from about 6 to 100 Å, and more preferably less than about 20 Å. In other embodiments, the gate dielectric 121 may include a high-k dielectric having a k-value substantially greater than about 7. Possible high-k dielectrics include Ta₂O₅, TiO₂, Al₂O₃, ZrO₂, HfO₂, Y₂O₃, L₂O₃, and their aluminates and silicates. Other suitable high-k gate dielectrics may include a haftnium-based materials such as HfO₂, HfSiOₓ, HfAlOₓ.

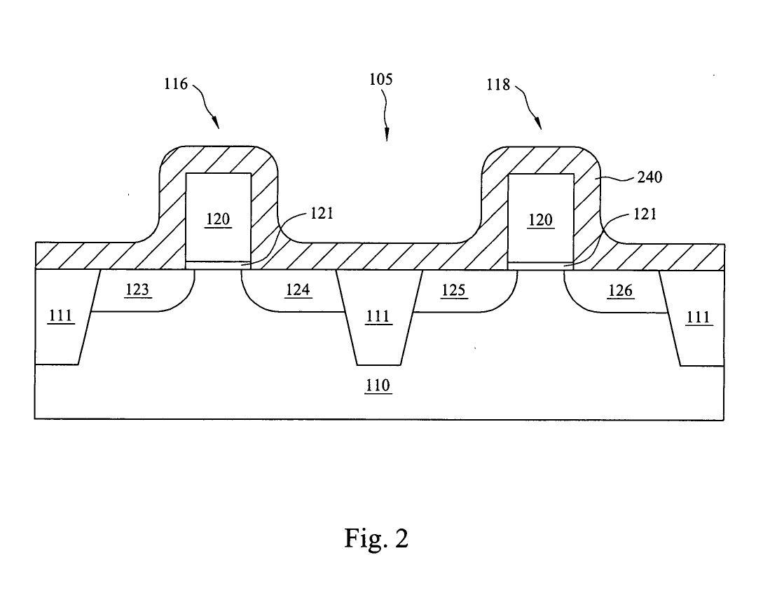

Turning now to FIG. 2, there is illustrated the structure of FIG. 1 after further processing according to an embodiment of the invention. A stress layer 240 is formed over the CMOS device 105 including at least one NMOS 116 and one PMOS 118 device. Stress layer 240 is preferably about 200 to 1000 Å thick. Stress layer 240 preferably comprises a compressive stress layer. In other embodiments, the stress layer 240 comprises a tensile stress layer. The magnitude of the stress in the stress layer 240 is preferably between about 500 MPa and 3 GPa.

In an embodiment, the stress layer 240 may comprise a contact etch stop layer, such as silicon nitride (Si₃N₄ or just SiNₓ). Stoichiometric silicon nitride films are known to be highly tensile stressed on silicon. However, the tensile stress may be greatly lowered and even turned into compressive stress by adjusting the Si/N ratio. That is, embodiments may convert one type to an opposite type of stress, i.e., tensile to compressive, or compressive to tensile. Generally, adding more silicon makes the silicon nitride film more compressive, while adding more nitrogen makes it more tensile. For example, the intrinsic stress of silicon nitride on silicon is preferably adjusted from about 300 to 1700 MPa through the Si/N ratio.

The compressive stress layer 240 is preferably comprised of silicon nitride (Si₃N₄ or just SiNₓ), silicon oxynitride (SiON), oxide, nitride, SiGe, Si-rich nitride, or a N-rich nitride. The compressive stress layer 240 is more preferably SiN or SiON and is most preferably SiON. It has a thickness from about 200 to 1000 Å, and preferably from about 250 to 500 Å. The compressive stress layer 240 is preferably deposited by plasma enhanced chemical vapor deposition (PECVD). PECVD conditions include a temperature from about 300 to 600° C. Deposition time is about 10 to 500 seconds and preferably about 20 to 120 seconds. A reactant NH3:SiH4 gas ratio is about 4:1 to 10:1, and preferably less than about 8:1. Alternative reactants include a di-saline:NH3 gas ratio about 1:4 to 1:10, and preferably less than about 1:1. The deposition pressure is preferably about 1.0 to 1.5 Torr. The PECVD power used to form the compressive stress layer 240 is preferably about 1000 to 2000 W and more preferably greater than about 1000 W.

In alternative embodiments, forming the stress layer, such as compressive or tensile, comprises a process selected from the group consisting essentially of a plasma enhanced chemical vapor deposition (PECVD), low pressure chemical vapor deposition (LPCVD), atomic layer deposition (ALD), physical vapor deposition (PVD), rapid thermal chemical vapor deposition (RTCVD), or combinations thereof.

In alternative embodiments, wherein the stress layer 240 is a tensile stress layer, suitable materials include tetraethylorthosilicate (TEOS), silicon oxynitride (SiON), oxide, nitride, silicon carbon, Si-rich nitride, or a N-rich nitride, and it is preferably SiN or SiON, in addition to silicon nitride. The tensile stress layer 240 has a thickness from about 200 to 1000 Å, and preferably from about 250 to 500 Å. The tensile stress layer 240 is preferably deposited by low pressure chemical vapor deposition (LPCVD). The LPCVD temperature is 350 to 800° C., and preferably from about 400 to 700° C. Reaction time is about 10 to 2000 seconds, and preferably about 20 to 120 seconds. The NH₃:SiH₄ gas ratio is about 50:1 to 400:1, and preferably less than about 700:1. An alternative reactant composition includes a di-saline:NH₃ gas ratio about 1:40 to 1:500, and preferably less than about 1:1. The deposition pressure is preferably about 10 to 400 Torr, and preferably less than about 300 Torr.

As is known in the art, a stress layer 240 such as that illustrated in FIG. 2 is known to induce a stress in the channel between the source/drain regions of a MOS device. For example, a highly tensile stress/strain film is known to induce a tensile channel stress/strain. Likewise, a highly compressive stress/strain film is known to induce a compressive channel stress/strain. As described below, embodiments of the invention include depositing a uniform stress film over a CMOS device and thereafter modulating or adjusting an appropriate stress property of the film in order to achieve a desired channel stress.

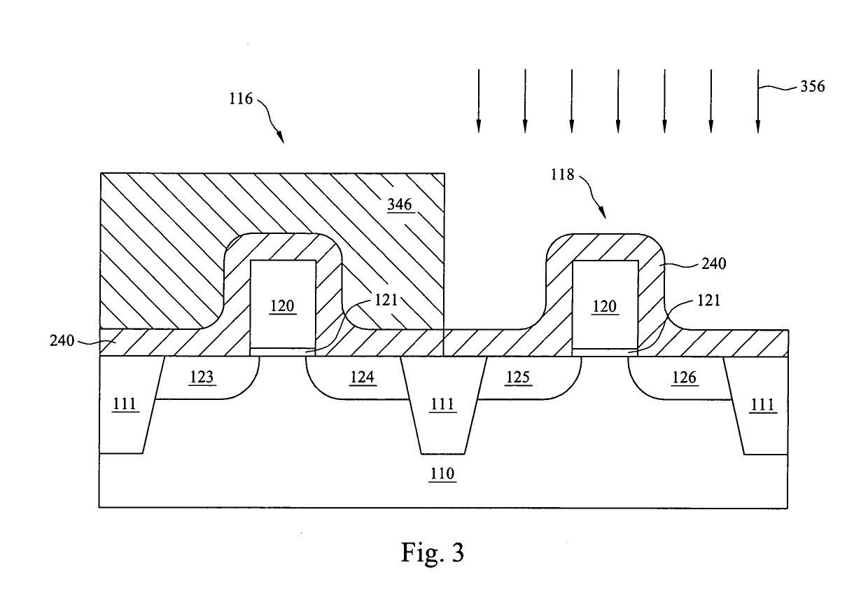

Turning now to FIG. 3, a masking layer 346 is formed at least over either the NMOS device 116 or the PMOS device 118. Masking layer 346 may include a photoresist or a hardmask. Suitable hardmasks include oxides, nitrides, oxynitrides, or silicon carbide, for example. As illustrated in FIG. 3, the masking layer 346 is selectively formed over the NMOS device 116, thereby leaving the PMOS device 118 and the overlying compressive stress layer 240 exposed.

After forming the masking layer 346, preferred embodiments include performing a treatment 356 aimed at adjusting the stress/strain distribution or modulating a stress magnitude in a portion of the stress layer 240. Treatments 356 may include local stress relaxation by ion bombardment or implantation using, for example, germanium, silicon, xenon, argon, oxygen, nitrogen, carbon, or germanium, and combinations thereof. Other treatments 356 may include changing the composition (e.g., oxidation and/or nitridation) of the stress layer 240 using, for example, a process such as thermal, plasma, ozone, UV, a steam oxidation, a steam environment, and/or combinations thereof. Other treatment methods 356 may include film densification using, for example, a zone treatment, e-beam curing, UV curing, laser treatment (either with or without an absorption or reflection capping layer).

By way of example, Applicants find that an as-deposited silicon nitride layer may have a 0.6 GPa intrinsic stress. Oxygen bombardment may reduce the stress below 0.2 GPa. On the other hand, e-beam curing and UV curing may increase the intrinsic stress to about 0.8 GPa and 1.7 GPa, respectively. Stress layers from about −5.0 to +5.0 GPa, and beyond, are within the scope of embodiments of the invention.

In one embodiment, germanium, Ge, ion implantation is performed to alter the characteristics of a silicon nitride stress layer 240. The ion implantation process may be a conventional beam-line ion implantation process, a plasma immersion ion implantation (PIII), or any other ion implantation process known and used in the art. The dose of the ion implantation maybe in the range of about IE13 to about IE16 ions per square centimeter and the energy may be in the range of about 10 eV to about 100 keV. After the ion implantation process, the properties of the silicon nitride stress layer will be altered such that its intrinsic stress is changed. For example, the treatment 356 may continue until a region of the stress layer 240 becomes less compressive. In other embodiments, the treatment 356 may convert the stress layer 240 from one stress type to another, for example, compressive to tensile, or tensile to compressive.

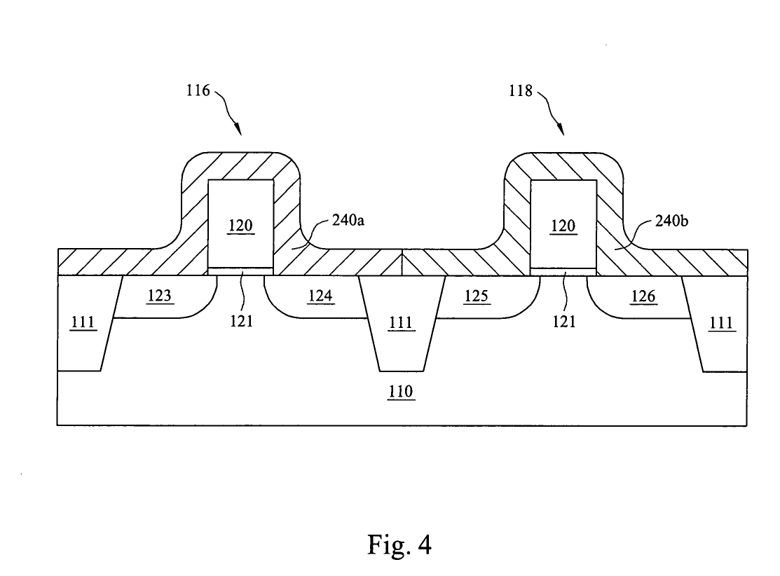

Turning now to FIG. 4, after completing the special stress treatment, the resist layer is removed. As shown in FIG. 4, the stress layer is comprised of two regions: a compressive stress region 240a and a stress adjusted region 240b. The stress adjusted region 240b of the stress layer may comprise a film that was originally highly compressive and is now less compressive, or highly tensile and is now less tensile. As in the preferred embodiment of FIG. 4, the stress adjusted region 240b is converted from a compressive layer to a tensile layer.

Generally, preferred embodiments of the invention comprise treating a portion of the stress layer so that the portion changes from having a first intrinsic stress to having a second intrinsic stress. As noted above, the treating may comprise adjusting a stress layer property using thermal oxidation, plasma oxidation, ultraviolet (UV) oxidation, steam oxidation, thermal nitridation, plasma nitridation, UV nitridation, or steam nitridation. Other methods include a zone treatment, UV curing, laser anneal, or flash anneal.

Other embodiments of the invention provide a semiconductor device such as a MOS or CMOS transistor having strain-enhanced carrier mobility. In an embodiment, a semiconductor device comprises an NMOS transistor having an NMOS gate electrode spacer, wherein the spacer comprises a material having a first intrinsic stress. An embodiment may further comprise a PMOS transistor formed in the substrate, the PMOS transistor comprising a PMOS gate electrode spacer, wherein the PMOS gate electrode spacer comprises a material having a second intrinsic stress. Preferably, the first intrinsic stress is one of compressive and tensile, and the third stress is the other of compressive and tensile. In other preferred embodiments, the second intrinsic stress is one of compressive and tensile, and the fourth stress is the other of compressive and tensile. In other embodiments, the first and second intrinsic stress are of the same type, i.e., both compressive or both tensile. In embodiments wherein both intrinsic stresses are of the same type, the difference is preferably at least a factor of two (100%).

In preferred embodiments of the invention, the substrate lattice spacing in the NMOS or PMOS carrier channel is strained at least 0.10%. For a silicon substrate, the substrate lattice spacing is about 5.4 Å (5.4295 Å) at about 25° C. In the case of silicon, a 0.1% strain corresponds to lattice displacement of about 0.0054 Å.

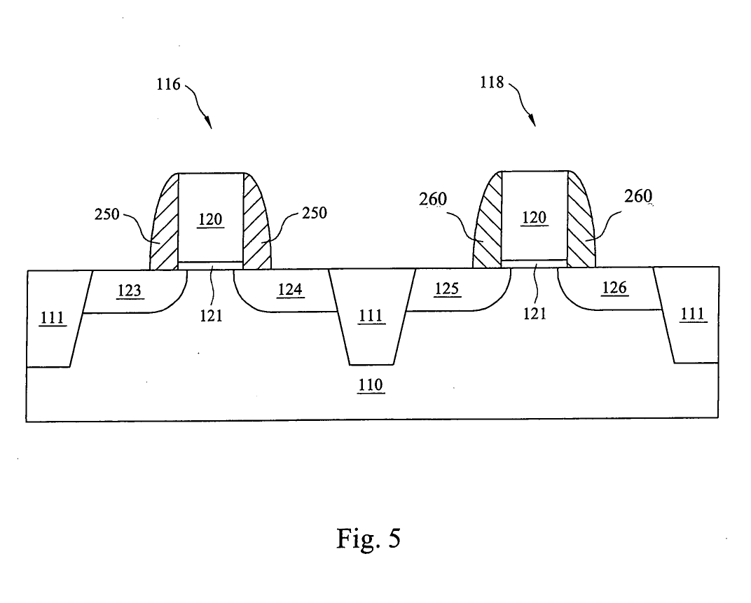

Next as shown in FIG. 5, layer 240 is etched to formed NMOS sidewall spacers 250 and PMOS sidewall spacers 260, which are formed on opposite sides of the gate dielectric 121 and gate electrode 120 of their respective device. Anisotropically etching the stress layer (240a and 240b) from the horizontal surfaces leaves the spacers 250 and 260.

While other workers describe the beneficial effects of I-shaped and L-shaped spacers, Applicants find that the D-shaped spacers (see e.g., 250 and 260) of FIG. 5 are particularly advantageous. For example, workers in the art describe an L-shaped spacer having an intrinsic tensile stress that induces a tensile stress in a MOSFET channel. Applicants, on the other hand, discovered that the D-shaped spacer of preferred embodiments, produces the contrary result, i.e. a D-shaped spacer having an intrinsic tensile stress induces a compressive stress in the MOSFET channel. Likewise, a D-shaped spacer having an intrinsic compressive stress induces a tensile stress in the MOSFET channel.

In FIG. 5, the spacers are illustrated as being comprised of a single layer. However, multi-layer spacers are within embodiments of the invention. Alternative embodiments of the invention preferably include spacers having a D-shape or at least a D-shaped part.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a substrate;
an NMOS transistor formed in the substrate, the NMOS transistor comprising an NMOS gate electrode spacer, wherein the NMOS gate electrode spacer comprises a material having a first intrinsic stress, and wherein the NMOS gate electrode spacer creates a third stress in an NMOS carrier channel; and
a PMOS transistor formed in the substrate, the PMOS transistor comprising a PMOS gate electrode spacer, wherein the PMOS gate electrode spacer comprises a material having a second intrinsic stress, and wherein the PMOS gate electrode spacer creates a fourth stress in a PMOS carrier channel;
wherein, the first intrinsic stress is one of compressive and tensile, and the third stress is the other of compressive and tensile, and wherein the second intrinsic stress is one of compressive and tensile, and the fourth stress is the other of compressive and tensile.

2. The semiconductor device of claim 1, wherein the NMOS and PMOS gate electrode spacers comprise D-shaped spacers.

3. The semiconductor device of claim 1, wherein the first intrinsic stress and the second intrinsic stress are compressive.

4. The semiconductor device of claim 1, wherein the first intrinsic stress and the second intrinsic stress are tensile.

5. The semiconductor device of claim 1, wherein a magnitude of the second intrinsic stress is less than half a magnitude of the first intrinsic stress.

6. The semiconductor device of claim 1, wherein the NMOS and PMOS gate electrode spacers independently comprise a material selected from the group consisting essentially of silicon-rich nitride, nitrided silicon oxide (SiON), silicon nitride, and combinations thereof.

7. A semiconductor device comprising:
an NMOS transistor and a PMOS transistor formed in a substrate;
the NMOS transistor comprising an NMOS gate electrode spacer, wherein the NMOS gate electrode spacer comprises a material having an intrinsic compressive stress;
the PMOS transistor comprising a PMOS gate electrode spacer, wherein the PMOS gate electrode spacer comprises a material having an intrinsic second stress, the intrinsic second stress being different from the intrinsic compressive stress;
wherein the NMOS gate electrode spacer creates a tensile stress in an NMOS carrier channel, and the PMOS gate electrode spacer creates a third stress in a PMOS carrier channel.

8. The semiconductor device of claim 7, wherein the third stress comprises a compressive stress.

9. The semiconductor device of claim 7, wherein the third stress comprises a tensile stress.

10. The semiconductor device of claim 7, wherein the NMOS and PMOS gate electrode spacers comprise D-shaped spacers.

11. The semiconductor device of claim 7, wherein a length of the NMOS carrier channel and the PMOS carrier channel is less than about 100 nm.

12. The semiconductor device of claim 7, wherein the substrate comprises a material selected from the group consisting essentially of silicon, silicon germanium, or combinations thereof.

13. The semiconductor device of claim 7, wherein the material having an intrinsic compressive stress comprises a material selected from the group consisting essentially of a silicon-rich nitride, nitrided silicon oxide (SiON), silicon nitride, silicon germanium, and combinations thereof.

14. The semiconductor device of claim 7, wherein the material having an intrinsic second stress comprises a material selected from the group consisting essentially of a silicon-rich nitride, nitrided silicon oxide (SiON), silicon nitride, silicon carbide, and combinations thereof.

15. The semiconductor device of claim 7, wherein the intrinsic compressive stress is between about 500 MPa and 3 GPa.

16. The semiconductor device of claim 7, wherein the tensile stress is between about 500 MPa and 3 GPa.

17. The semiconductor device of claim 7, wherein at least one of the NMOS carrier channel and the PMOS carrier channel has at least a 0.1% strain.
